(19) United States
(12) Patent Application Publication
(10) Pub. No.: US 2009/0295476 A1
(43) Pub. Date: Dec. 3, 2009

(54) FULLY DIFFERENTIAL DC OFFSET DEVICE CIRCUIT

(76) Inventor: Tsong-Chi HUANG, Taipei County (TW)

Correspondence Address: Muncy, Geissler, Olds & Lowe, PLLC, P.O. BOX 1364, FAIRFAX, VA, 22038-1364, US

(21) Appl. No.: 12/469,110

(22) Filed: May 20, 2009

(30) Foreign Application Priority Data
May 27, 2008 (TW) 097119492

(51) Int. Cl. H03F 3/45

(52) U.S. Cl. 330/252

(57) ABSTRACT

A fully differential DC offset device circuit utilized in a high-pass filter is provided. The fully differential DC offset device circuit includes a first amplifying circuit, a second amplifying circuit and a Miller capacitor. The first amplifying circuit includes a first transistor and a second transistor, wherein a base of the first transistor is electrically connected to a base of the second transistor. The second amplifying circuit includes a third transistor and a fourth transistor, wherein a base of the third transistor is electrically connected to a base of the fourth transistor. The Miller capacitor includes an amplifier, wherein a first input terminal of the amplifier is electrically connected to the base of the second transistor of the first amplifying circuit, and a second input terminal of the amplifier is electrically connected to the base of the third transistor of the second amplifying circuit.

### CROSS REFERENCE TO RELATED APPLICATIONS

This Application claims priority of Taiwan Patent Application No. 097119492, filed on May 27, 2008, the entirety of which is incorporated by reference herein.

### BACKGROUND OF THE INVENTION

1. Field of the Invention

The present invention relates to a fully differential DC offset device circuit, and in particular relates to a fully differential DC offset device circuit utilized in a high-pass filter.

2. Description of the Related Art

Conventional high-pass filters comprise two variable gain amplifying circuits and a large-sized capacitor. The large-sized capacitor electrically is connected between those two variable gain amplifying circuits to realize high-pass filtration.

FIG. 1 shows a structure of a conventional high-pass filter. As shown in FIG. 1, the high-pass filter 1 includes the first variable gain amplifying circuit 11 and the second variable gain amplifying circuit 12. The large-sized capacitor 13 electrically connects between the first variable gain amplifying circuit 11 and the second variable gain amplifying circuit 12 for charge and discharge to achieve a high-pass filtering function for the high-pass filter 1.

For discharge and charge of high current, the size of the large-sized capacitor 13 can not be reduced to small scale. Accordingly, the high-pass filter 1 has larger size and more cost resulted from the large-sized capacitor 13 cannot be incorporated into a single chip with the first variable gain amplifying circuit 11 and the second variable gain amplifying circuit 12. For the forgoing, a smaller large-sized capacitor is desired.

### BRIEF SUMMARY OF THE INVENTION

A detailed description is given in the following embodiments with reference to the accompanying drawings.

A fully differential DC offset device circuit utilized in a high-pass filter is provided. The fully differential DC offset device circuit comprises a first amplifying circuit, a second amplifying circuit and a Miller capacitor. The first amplifying circuit comprises a first transistor and a second transistor, wherein a base of the first transistor is electrically connected to a base of the second transistor. The second amplifying circuit comprises a third transistor and a fourth transistor, wherein a base of the third transistor is electrically connected to a base of the fourth transistor. The Miller capacitor comprises an amplifier, wherein a first input terminal of the amplifier is electrically connected to the base of the second transistor of the first amplifying circuit, and a second input terminal of the amplifier is electrically connected to the base of the third transistor of the second amplifying circuit.

### BRIEF DESCRIPTION OF THE DRAWINGS

The present invention can be more fully understood by reading the subsequent detailed description and examples with references made to the accompanying drawings, wherein:

FIG. 1 shows a structure of a conventional high-pass filter; and

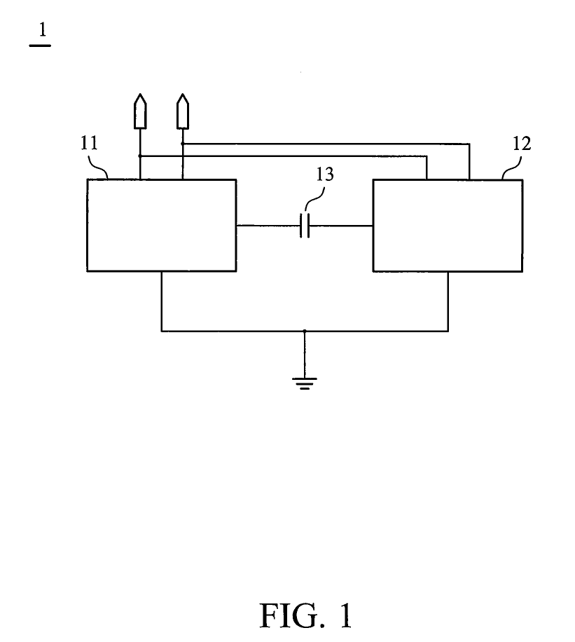

FIG. 2 shows a fully differential DC offset device circuit of a preferred embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

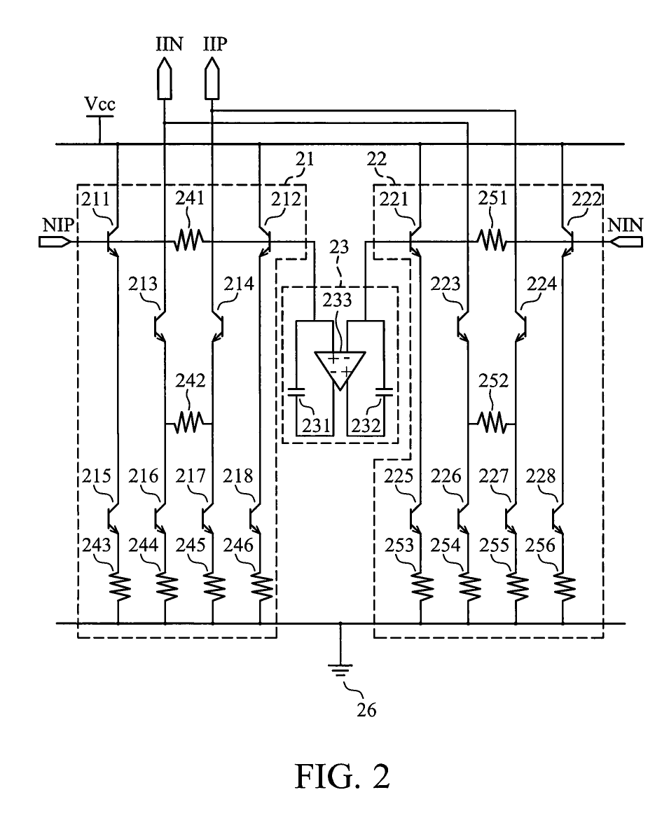

FIG. 2 shows a fully differential DC offset device circuit of a preferred embodiment of the invention. As shown in FIG. 2, the fully differential DC offset device circuit 2 comprises a first amplifying circuit 21, a second amplifying circuit 22, a Miller capacitor 23 and a ground terminal 26. A terminal of the Miller capacitor 23 is electrically connected to the first amplifying circuit 21 and the other terminal thereof is electrically connected to the second amplifying circuit 22.

The first amplifying circuit 21 comprises a first transistor 211, a second transistor 212, a fifth transistor 213, a sixth transistor 214, a ninth transistor 215, a tenth transistor 216, an eleventh transistor 217 and a twelfth transistor 218. The first amplifying circuit 21 further comprises a first resistor 241, a third resistor 242, a fifth resistor 243, a sixth resistor 244, a seventh resistor 245 and an eighth resistor 246.

The collector of the first transistor 211 is electrically connected to a voltage source Vcc, and the base thereof is electrically connected to a first terminal of the first resistor 241. The collector of the second transistor 212 is electrically connected to the voltage source Vcc, and the base thereof is electrically connected to a second terminal of the first resistor 241. The collector of the fifth transistor 213 is electrically connected to a negative current source IIN, and the base thereof is electrically connected to the emitter of the first transistor 211. The collector of the sixth transistor 214 is electrically connected to a positive current source IIP, and the base thereof is electrically connected to the emitter of the second transistor 212. A first terminal of the third resistor 242 is electrically connected to the emitter of the fifth transistor 213, and the second terminal thereof is electrically connected to the emitter of the sixth transistor 214.

The collector of the ninth transistor 215 is electrically connected to the emitter of the first transistor 211, and the emitter of the ninth transistor 215 is electrically connected to a first terminal of the fifth resistor 243. The collector of the tenth transistor 216 is electrically connected to the emitter of the fifth transistor 213, and the emitter of the tenth transistor 216 is electrically connected to a first terminal of the sixth resistor 244. The collector of the eleventh transistor 217 is electrically connected to the emitter of the sixth transistor 214, and the emitter of the eleventh transistor 217 is electrically connected to a first terminal of the seventh resistor 245. The collector of the twelfth transistor 218 is electrically connected to the emitter of the second transistor 212, and the emitter of the twelfth is electrically connected to a first terminal of the eighth resistor 246. Bases of the ninth transistor 215, the tenth transistor 216, the eleventh transistor 217 and the twelfth transistor 218 are electrically connected to each other, and second terminals of the fifth resister 243, the sixth resistor 244, the seventh resistor 245 and the eighth resistor 246 are electrically connected to the ground terminal 26.

The second amplifying circuit 22 comprises a third transistor 221, a fourth transistor 222, a seventh transistor 223, a eighth transistor 224, a thirteenth transistor 225, a fourteenth transistor 226, a fifteenth transistor 227 and a sixteenth transistor 228. The second amplifying circuit 22 further comprises a second resistor 251, a fourth resistor 252, a ninth resistor 253, a tenth resistor 254, an eleventh resistor 255 and an twelfth resistor 256.

The collector of the third transistor 221 is electrically connected to the voltage source Vcc, and the base of the third transistor 221 is electrically connected to a first terminal of the second resistor 251. The collector of the fourth transistor 222 is electrically connected to the voltage source Vcc, and the base of the fourth transistor 222 is electrically connected to a second terminal of the second resistor 251. The collector of the seventh transistor 223 is electrically connected to the negative current source IIN, and the base of the seventh transistor 223 is electrically connected to the emitter of the third transistor 221. The collector of the eighth transistor 224 is electrically connected to a positive current source IIP, and the base of the eighth transistor 224 is electrically connected to an emitter of the fourth transistor 222. A first terminal of the fourth resistor 252 is electrically connected to the emitter of the seventh transistor 223, and a second terminal thereof is electrically connected to the emitter of the eighth transistor 224.

The collector of the thirteenth transistor 225 is electrically connected to the emitter of the third transistor 221, and the emitter of the thirteenth transistor 225 is electrically connected to a first terminal of the ninth resistor 253. The collector of the fourteenth transistor 226 is electrically connected to the emitter of the seventh transistor 223, and the emitter of the fourteenth transistor is electrically connected to a first terminal of the tenth resistor 254. The collector of the fifteenth transistor 227 is electrically connected to the emitter of the eighth transistor 224, and the emitter of the fifteenth transistor is electrically connected to a first terminal of the eleventh resistor 255. The collector of the sixteenth transistor 228 is electrically connected to the emitter of the fourth transistor 222, and the emitter of the sixteenth transistor 228 is electrically connected to a first terminal of the twelfth resistor 256. Bases of the thirteenth transistor 225, the fourteenth transistor 226, the fifteenth transistor 227 and the sixteenth transistor 228 are electrically connected to each other, and second terminals of the ninth resister 253, the tenth resistor 254, the eleventh resistor 255 and the twelfth resistor 256 are electrically connected to the ground terminal 26.

The Miller capacitor 23 comprises a first capacitor 231, a second capacitor 232 and an amplifier 233. The first capacitor 231 is electrically connected to a positive process terminal of the amplifier 233 and a positive signal input source NIP. The second capacitor 232 is electrically connected to a negative process terminal of the amplifier 233 and a negative signal input source NIN. In the preferred embodiment, the amplifier 233 includes a fully differential amplifier with a common mode feedback circuit. Because the output voltage of the amplifier 233 has a predetermined voltage value, the initial charge of capacitors can start in a predetermined voltage value to reduce the charge time from low voltage to the predetermined voltage.

The fully differential DC offset device circuit processes the positive signal input source NIP and the negative signal input source NIN through the first amplifying circuit 21 and the second amplifying circuit 22. In the embodiment, the first amplifying circuit 21 and the second amplifying circuit 22 includes variable gain amplifying circuits. The Miller capacitor 23 is connected between above two variable gain amplifying circuits and performs a high-pass filtering process. According to the above circuitry of FIG. 2, the evaluated capacitance Cext equals as the capacitance Cp of the first capacitor 231 and the second capacitor 232 multiplied by an amplifying multiple of the amplifier 233. This replaces the large-sized capacitor by smaller capacitors to decrease chip's cost and size, and to incorporate those small capacitors and circuits into a single chip.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A fully differential DC offset device circuit utilized in a high-pass filter, comprising:
a first amplifying circuit having a first transistor and a second transistor, wherein the base of said first transistor is electrically connected to the base of said second transistor;
a second amplifying circuit having a third transistor and a fourth transistor, wherein the base of said third transistor is electrically connected to the base of said fourth transistor; and
a Miller capacitor having a amplifier, wherein a first input terminal of said amplifier is electrically connected to the base of said second transistor of said first amplifying circuit, and a second input terminal of said amplifier is electrically connected to the base of said third transistor of said second amplifying circuit.

2. The fully differential DC offset device circuit as claimed in claim 1, wherein the base of said first transistor of said first amplifying circuit is electrically connected to a first terminal of a first resistor, and said second transistor is electrically connected to a second terminal of said first resistor.

3. The fully differential DC offset device circuit as claimed in claim 1, wherein the base of said third transistor of said second amplifying circuit is electrically connected to a first terminal of a second resistor, and said fourth transistor is electrically connected to a second terminal of said second resistor.

4. The fully differential DC offset device circuit as claimed in claim 1, wherein said first amplifying circuit further comprises a fifth transistor and a sixth transistor, the emitter of said fifth transistor is electrically connected to a first terminal of a third resistor, and the emitter of said sixth transistor is electrically connected to a second terminal of said third resistor.

5. The fully differential DC offset device circuit as claimed in claim 1, wherein said second amplifying circuit further comprises a seventh transistor and a eighth transistor, the emitter of said seventh transistor is electrically connected to a first terminal of a fourth resistor, and the emitter of said eighth transistor is electrically connected to a second terminal of said fourth resistor.

6. The fully differential DC offset device circuit as claimed in claim 1, wherein a first amplifying circuit further comprises a ninth transistor, a tenth transistor, an eleventh transistor and a twelfth transistor, and bases of said ninth transistor, said tenth transistor, said eleventh transistor and said twelfth transistor are electrically connected to each other.

7. The fully differential DC offset device circuit as claimed in claim 1, wherein a second amplifying circuit further comprises a thirteenth transistor, a fourteenth transistor, a fifteenth transistor and a sixteenth transistor, and bases of said thirteenth transistor, said fourteenth transistor, said fifteenth transistor and said sixteenth transistor are connected to each other.

8. The fully differential DC offset device circuit as claimed in claim 1, wherein said Miller capacitor further comprises a first capacitor and a second capacitor, said first capacitor electrically connects between said first input terminal and a first output terminal of said amplifier of said Miller capacitor, and said second capacitor electrically connects between said second input terminal and a second output terminal of said amplifier.
